(19) United States
(12) Patent Application Publication
(10) Pub. No.: US 2014/0070309 A1
(43) Pub. Date: Mar. 13, 2014

(54) SEMICONDUCTOR DEVICE AND MANUFACTURING METHOD OF THE SAME

(71) Applicant: KABUSHIKI KAISHA TOSHIBA, Tokyo (JP)

(72) Inventor: Takayuki Sakai, Ishikawa (JP)

(73) Assignee: Kabushiki Kaisha Toshiba, Tokyo (JP)

(21) Appl. No.: 13/784,751

(22) Filed: Mar. 4, 2013

(30) Foreign Application Priority Data
Sep. 11, 2012 (JP) 2012-199774

(51) Int. Cl. H01L 27/07; H01L 21/8232

(52) U.S. Cl. CPC H01L 27/07; H01L 21/8232
USPC 257/334; 438/270

(57) ABSTRACT

A semiconductor device is provided with a semiconductor substrate including a drain layer of a first conductivity type, a base layer of a second conductivity type, and a source layer of the first conductivity type, a gate insulating film, a gate electrode, an insulating section, a source electrode, and a drain electrode. Gate trenches are formed on an upper surface of the semiconductor substrate. A curved section is formed on the upper surface of the semiconductor substrate between the gate trenches in the semiconductor substrate. The base layer is disposed between the gate trenches, and the source layer is formed above the base layer at both ends of the curved section.

### CROSS-REFERENCE TO RELATED APPLICATION

This application is based upon and claims the benefit of priority from Japanese Patent. Application No. 2012-199774, filed Sep. 11, 2012; the entire contents of which are incorporated herein by reference.

### FIELD

Embodiments described herein relate to a semiconductor device and a manufacturing method thereof.

### BACKGROUND

A vertical MOSFET (metal-oxide-semiconductor field-effect transistor) with a trench gate structure has been developed. In the vertical MOSFET with a trench gate structure, a gate trench stretching in one direction from an upper surface of a semiconductor substrate occurs. A gate electrode is filled inside the gate trench, a source electrode formed on the upper surface of the semiconductor substrate and a drain electrode formed on the lower surface of the semiconductor substrate. A source contact structure for connecting the source electrode to the semiconductor substrate is then formed in the area between the gate trenches that are present on the upper surface of the semiconductor substrate. A gate trench in which a gate electrode is buried and the source contact structure are formed by separate lithographies.

To decrease the on-resistance of a power semiconductor device, the alignment cycle of the gate trench is made short and the MOS structure is made smaller. Unfortunately, if the alignment cycle of the gate trench is made short, the composite gap between the gate trench and source contact structure becomes relatively larger and forming the source contact structure becomes harder.

### DESCRIPTION OF THE DRAWINGS

FIG. 1 is a cross-sectional diagram that snows a semiconductor device of a first embodiment.

FIGS. 2A-2C are cross-sectional diagrams that shows a manufacturing method of the semiconductor device of the first embodiment.

FIGS. 3A-3C are cross-sectional diagrams that show the manufacturing method of the semiconductor device of the first embodiment.

FIGS. 4A-4C are cross-sectional diagrams that show a manufacturing method of the semiconductor device of the first embodiment.

FIGS. 5A-5E are cross-sectional diagrams that show samples for which CDE (chemical dry etching) is performed under different temperatures.

FIGS. 6A-6C are cross-sectional diagrams that show a mechanism by which a working surface becomes round when the temperature is relatively low.

FIGS. 6D-6F are cross-sectional diagrams that show a mechanism by which a working surface becomes flat when the temperature is relatively high.

FIG. 7 is a cross-sectional diagram that show a sample for which CDE is performed under different temperatures and different gas flow ratios.

FIGS. 8A-8C are cross-sectional diagrams that show a method of manufacturing a semiconductor device according to a first comparative example.

FIGS. 9A-9C are cross-sectional diagrams that show a method of manufacturing a semiconductor device according to a second comparative example.

FIG. 10 is cross-sectional diagram that shows a semiconductor device of a second embodiment.

FIGS. 11A-11B are cross-sectional diagrams of a manufacturing method of the semiconductor device of the second embodiment.

FIG. 12 is a cross-sectional diagram that shows a semiconductor device of a third embodiment.

FIGS. 13A-13C are cross-sectional diagrams that show a manufacturing method of the semiconductor device of the third embodiment.

FIG. 14 is a cross-sectional diagram that shows the semiconductor device of the third embodiment having an alternative structure.

### DETAILED DESCRIPTION

Embodiments provide a highly reliable miniaturized semiconductor device and a manufacturing method thereof. The embodiments are described below with reference to the drawings.

### First Embodiment

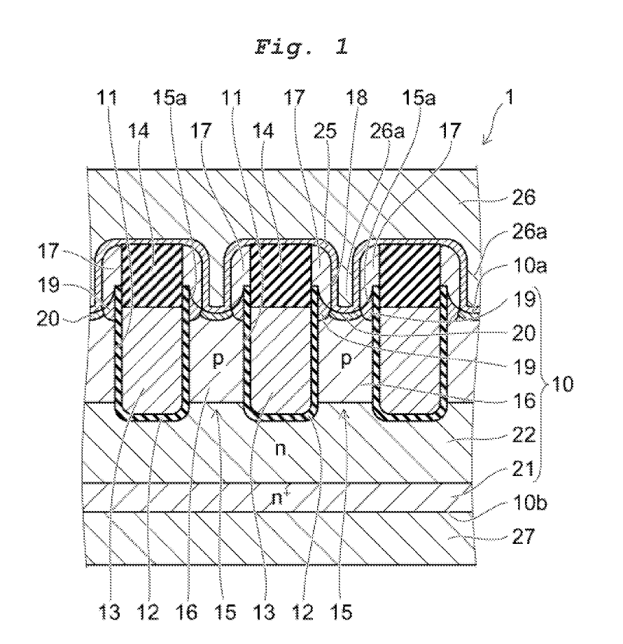

FIG. 1 is a cross-sectional diagram that shows a semiconductor device of a first embodiment. A vertical MOSFET with a trench gate structure is formed in the semiconductor device of the first embodiment.

The semiconductor device of the first embodiment is provided with A semiconductor device is provided with a semiconductor substrate including a drain layer of a first conductivity type, a base layer of a second conductivity type, and a source layer of the first conductivity type, a gate insulating film, a gate electrode, an insulating section, a source electrode, and a drain electrode. Gate trenches are formed on an upper surface of the semiconductor substrate. A curved section is formed on the upper surface of the semiconductor substrate between the gate trenches in the semiconductor substrate. The base layer is disposed between the gate trenches, and the source layer is formed above the base layer at both ends of the curved section.

The manufacturing method of the semiconductor device of the first embodiment includes forming multiple gate trenches in a semiconductor substrate having a drain layer of a first conductivity type and a base layer of a second conductivity type above the drain layer and between the gate trenches, forming a gate insulating film made of silicon oxide on inner surfaces of the gate trenches, forming a gate electrode on a lower part of each gate trench, forming an insulating section on an upper part of each gate trench, forming a curved concave section on an upper surface of the semiconductor substrate so that both ends of the curved concave section is located higher than an upper surface of the gate electrode, forming a source layer of a first conductivity type at both ends of the curved concave section, forming a source electrode electrically connected to the source layer, and forming a drain electrode electrically connected to the drain layer. The curved concave section is formed by performing chemical dry etching under conditions where a ratio of a flow rate of oxygen gas to a flow rate of carbon tetrafluoride gas is 1.6 or more and the temperature is 40° C. or less.

As shown in FIG. 1, in a semiconductor device 1 of the first embodiment, a silicon substrate 10 is formed. The lower layer of the silicon substrate 10 becomes a drain layer 21 of the n⁺ conductivity type. A drift layer 22 of the n conductivity type is formed on the drain layer 21. A base layer 16 of the p conductivity type is formed on the drift layer 22. A source layer 19 of the n+ conductivity type and a carrier pulling layer 20 of the p+ type are formed on the base layer 16. The source layer 19 and the carrier pulling layer 20 are exposed to an upper surface 10a of the silicon substrate 10 and are separated from the drift layer 22 by the base layer 16. The silicon substrate 10 is composed of the drain layer 21, drift layer 22, the base layer 16, the source layer 19, and the carrier pulling layer 20.

Further, “n+ type” shows that the effective concentration of dopants that become a donor is higher than the “n type”. Further, “p+ type” shows that the effective concentration of dopants that become an acceptor is higher than the “p type”. In this specification, “effective dopant concentration” means the concentration of dopants that contributes to the conductivity of the semiconductor material. For instance, when both the dopants (e.g., dopants that become the donor, and dopants that become the acceptor) are contained in the semiconductor material, the effective dopant concentration is concentration remaining after removing the complementing donor and acceptor parts.

Multiple gate trenches 11 are formed on the upper surface 10a of the silicon substrate 10. The gate trench 11 is extended in one direction and is arranged cyclically. The gate trench 11 passes through the base layer 16 and goes into the upper part of drift layer 22. A gate insulating film 12 made from silicon oxide material is formed on the inner surface of the gate trench 11. Moreover, conductive material, for instance, gate electrode 13 made of polysilicon, to which dopants are introduced, is fed into the lower part inside the gate trench 11.

Insulating material, for instance, an insulating section 14 made of silicon oxide material is formed on the gate electrode 13. The lower part of the insulating section 14 is arranged inside the upper part of the gate trench 11 and the upper part of the insulating section 14 protrudes from the upper surface 10a of the silicon substrate 10.

A section 15 (“mesa section 15”) between gate trenches 11 present on the silicon substrate 10 is in a stripe form extended in substantially the same direction as the gate trench 11. In short, the longitudinal direction of the mesa section 15 is a direction along which the gate electrode 13 extends. The width direction of the mesa section 15 is an array direction of the gate electrode 13. When observed from the longitudinal direction of the mesa section 15, an upper surface 15a of the mesa section 15 has a concave shape. As a result, with respect to the upper surface 15a of the mesa section 15, there is an area at both ends in the width direction of the mesa section 15 that is higher than the area at the central section in the width direction. More specifically, with respect to the upper surface 15a of the mesa section 15, there is an area at both ends in the width direction of the mesa section 15 that is higher than the upper surface of the gate electrode 13 and the area at the central section in the width direction of the mesa section 15 is at substantially the same height as that of the gate electrode 13.

Moreover, the source layer 19 is arranged at both ends in the width direction in the upper layer of the mesa section 15 and the carrier pulling layer 20 is arranged in the central section in the width direction in the upper layer of the mesa section 15. Accordingly, as seen from the longitudinal direction of the mesa section 15, the carrier pulling layer 20 is arranged between the pair of source layers 19. The base layer 16, the source layer 19 and the carrier pulling layer 20 are in a belt form extending in the longitudinal direction of the mesa section 15. Moreover, the upper surface of the source layer 19 and upper surface of the carrier pulling layer 20 constitute the upper surface 15a of the mesa section 15.

A side wall 17 made of epitaxial silicon or polysilicon is set on the side surfaces of the insulating section 14. The side wall 17 contains dopants that become the donor to silicon. In short, they are dopants that cause the silicon to become the n type. The effective dopant concentration of the side wall 17 is higher than the effective dopant concentration of the source layer 19. The side wall 17 is arranged in the upper part of the gate insulating film 12 as well as the upper area of the source layer 19 and comes in contact with the source layer 19. Moreover, the space between the side wall 17 in the upper area of the mesa section 15 right next to the side wall 17 becomes a source trench 18.

A barrier metal layer 25 is set in the upper direction of the silicon substrate 10, the side wall 17, and the insulating section 14 in such a way that the silicon substrate 10, the side wall 17, and the insulating section 14 are covered. The barrier metal layer 25 comes in contact with the silicon substrate 10, the side wall 17, and the insulating section 14. The barrier metal layer 25 is formed with conductive material such as titanium (Ti), titanium nitride (TiN), and/or tungsten nitride (WN).

For instance, a source electrode 26 that includes a metallic material such as tungsten (W), is formed on the barrier metal layer 25. The source electrode 26 comes into contact with the harrier metal layer 25. A part of the source electrode 26 fills the source trench 18. This part is a source contact 26a. The source contact 26a is connected to the source layer 19 through the barrier metal layer 25 and the side wall 17. Further, the source contact 26a is connected to the carrier pulling out layer 20 through the barrier metal layer 25. On the other hand, the source electrode 26 is insulated from the gate electrode 13 by the insulating section 14 and gate insulator 12.

A drain electrode 27, including a metallic material such as tungsten (W), is formed on a lower surface 10b of the silicon substrate 10. The drain electrode 27 is connected to the drain layer 21.

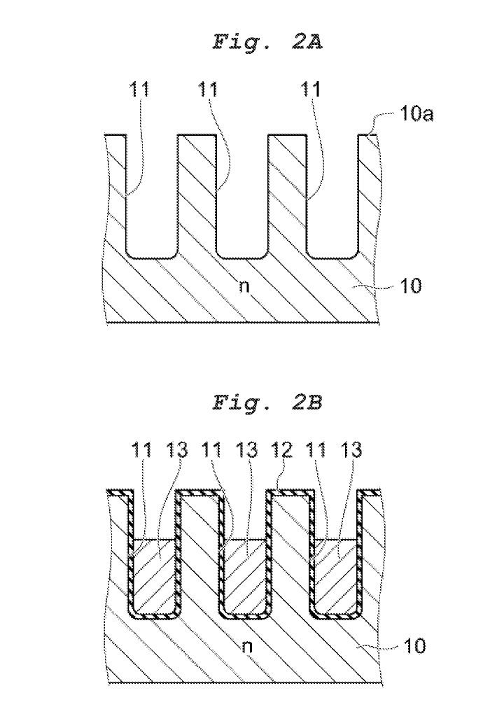

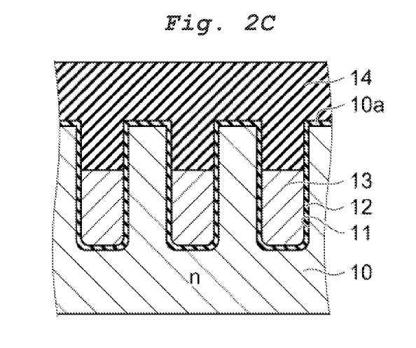

FIGS. 2A-2C, FIGS. 3A-3C, and FIGS. 4A-4C are cross-sectional diagrams that show a manufacturing method of the semiconductor device of the first embodiment. Typically, only the upper part of the central structure of the semiconductor device 1 is shown in FIGS. 2A-4C.

As shown in FIG. 2A, the silicon substrate 10 is prepared. At this point, the conductivity type of the silicon substrate 10 is the n type. Further, this conductivity type forms the drain layer 21 of the n+ type on the lower part of the silicon substrate 10 (refer to FIG. 1). Therefore, a part of the silicon substrate 10 other than the drain layer 21 becomes the drift layer 22 of the n type (refer to FIG. 1).

Further, for instance, two or more crate trenches 11 are formed on the upper surface 10a of the silicon substrate 10 by a lithography method. Gate trenches 11 extend in one direction, and formed so as to arrange periodically.

As shown in FIG. 2B, gate insulator 12 made of silicon oxide is formed on the silicon substrate 10. Gate insulator 12 is also formed on the inner side of the gate trench 11. The gate electrode 13 is formed on the lower part in the gate trench 11. The gate electrode 13 is made of conductive material, for instance, polysilicon containing dopants.

As shown in FIG. 2C, the insulating section 14 made of insulating material, for instance, silicon oxide, is deposited on all surfaces. The insulating section 14 is buried in the upper part in the gate trench 11 by which the insulating section 14 comes into contact with the gate electrode 13 and covers all surfaces of the upper surface 10a of the silicon substrate 10.

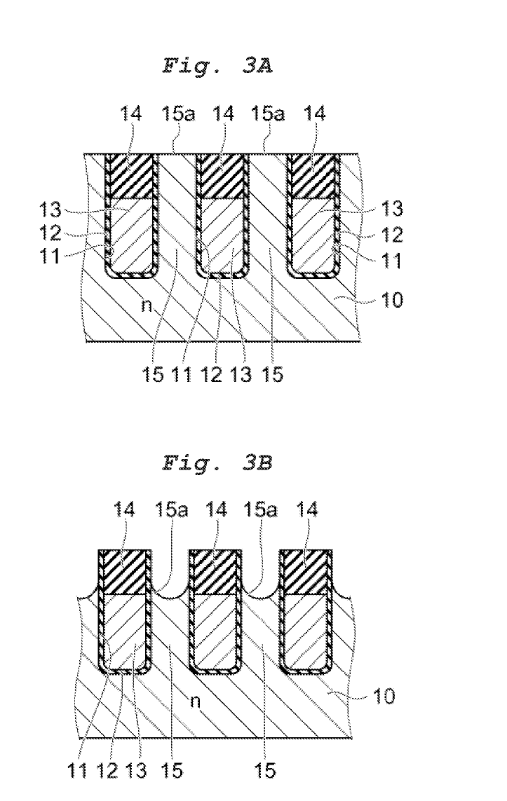

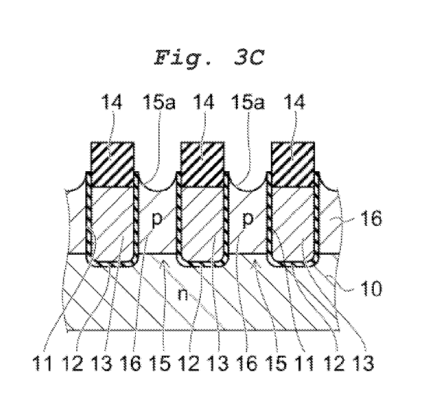

As shown in FIG. 3A, dry etching is performed on the insulating section 14, and the silicon substrate 10 is exposed. As a result, the upper surface of the insulating section 14 embedded in the gate trench 11 and the upper surface of the silicon substrate 10 between the gate trenches 11, in other words, the upper surface 15a of the mesa section 15, is located on almost the same surface.

As shown in FIG. 3B, chemical dry etching (CDE) is applied on all surfaces, and the upper surface 15a of the mesa section 15 of the silicon substrate 10 is pulled lower. During this CDE, the mixed gas of carbon tetrafluoride (CF₄) gas and oxygen (O₂) gas is used as an etching gas. The ratio (“gas flow ratio”) of the flow rate (sccm, standard cubic centimeter per minute) of the O₂ gas to the flow rate (sccm) of the CF₄ gas is 1.6 or more and the temperature is 40° C. or less. As a result, the shape of the upper surface 15a of the mesa section 15 has a curved, concave shape. The upper surface 15a at both ends in the width direction of the mesa section 15 is at a higher position than the upper surface of the gate electrode 13. The upper surface 15a at the central section in the width direction of the mesa section 15 is located at an almost equal height to the upper surface of the gate electrode 13.

As shown in FIG. 30, the base layer 16 is formed on the mesa section 15 by ion implantation of the acceptor dopants on the entire surface. Further, a naturally oxidized film (not shown in the drawing) formed on the upper surface 15a of the mesa section 15 is removed by performing wet etching using hydrofluoric acid. At that time although the exposed part of gate insulator 12 that includes the silicon oxide is removed, the part that covers the gate electrode 13 in the gate insulator 12 is covered by both ends of the mesa section 15. Therefore, etching cannot be performed on the covered part of gate insulator 12. The gate electrode 13 is not exposed by this etching. Moreover, the majority of the insulating section 14 remains.

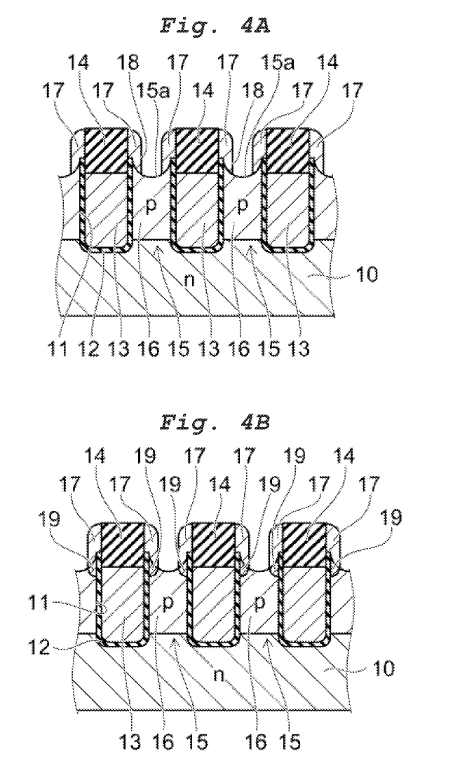

Then, silicon film (not shown in the drawing) is formed on the entire surface of the structure shown in FIG. 30. Further, this silicon film is etched and, as shown in FIG. 4A, the silicon film remains on the side surface of the insulating section 14 and the side wall 17 is formed. The side wall 17 includes epitaxial silicon or polysilicon to which donor dopants have been introduced. Moreover, the side wall 17 is arranged in the area immediately above both sides in the width direction in the mesa section 15. The space between side walls 17 in the area that is immediately above the mesa section 15 becomes the source trench 18 and a part of the upper surface 15a of the mesa section 15 is exposed to the bottom of the source trench 18.

As shown in FIG. 4B, dopants contained in the side wall 17 are diffused into the mesa section 15 by heat treatment. In this way, the source layer 19 of the n+ conductivity type is formed on the upper surface 15a of the mesa section that is immediately under the side wall 17.

As shown in FIG. 4C, by using the insulating section 14 and the side wall 17 as a mask, ion implantation of the acceptor dopants is performed by which carrier pulling out layer 20 having the p+ conductivity type is formed in the upper surface 15a of the mesa section 15 that is immediately below the source trench 18. As shown, carrier pulling out layer 20 is formed in the area between two source layers 19 in the upper surface 15a of the mesa section 15.

Referring back to FIG. 1, the barrier metal layer 25 is formed on the entire surface of the structure shown in FIG. 4G. Further, the source electrode 26 is formed on the barrier metal layer 25 by depositing metal, for instance, tungsten (W). A part of the source electrode 26 passes into the source trench 18, and the source contact 26a is formed therein. On the other hand, the drain electrode 27 is formed by depositing metal, for instance, tungsten, on the lower surface 10b of the silicon substrate 10. The drain electrode 27 is connected to the drain layer 21. Thus, semiconductor device 1 described in the first embodiment is manufactured.

An effect of the first embodiment is explained below. In the first embodiment, in the process shown in FIG. 2A, the gate trench 11 is formed on the silicon icon substrate 10. In the process shown in FIG. 3A, the insulating section 14 is embedded in the upper part of the gate trench 11. In the process shown in FIG. 4, the side wall 17 that contains dopants is formed. In the process shown in FIG. 4B, the source layer 19 is formed by diffusing the dopants from the side wall 17. In the process shown in FIG. 1, the source contact 26a is formed in the source trench 18, which is between side walls 17. As a result, after forming the gate trench 11, the source layer 19 and the source contact 26a can be formed by a self-aligning process. Accordingly, alignment shift cannot be generated between the gate trench 11, the source layer 19 and the source contact 26a. As a result, high reliability can be maintained in the semiconductor device 1, even if the semiconductor device 1 is miniaturized and the on-resistance is decreased.

Moreover, in the first embodiment, in the process shown in FIG. 3B, by applying CDE under fixed conditions, the upper surface 15a in the mesa section 15 can be formed in a curved, concave shape. As a result, both ends of the upper surface 15a in the width direction are at a higher position than the upper surface of the gate electrode 13. The central section in the width direction can be positioned at a lower position than end sections.

By locating both ends of the upper surface 15a in the width direction at a place that is at a higher position than the upper surface of the gate electrode 13, in the process shown in FIG. 3C, the part that covers the gate electrode 13 in gate insulator 12 is covered by the mesa section 15. Therefore, even if wet etching is performed to remove the natural oxidized film of the upper surface 15a, the gate electrode 13 is not exposed. As a result, in the process shown in FIG. 4A, the side wall 17 never comes into contact with the gate electrode 13. As a result, the short-circuit of the gate electrode 13 and the source electrode 26 can be prevented.

Moreover, the amount of overlap between the source layer 19 and the gate electrode 13 in the vertical direction can be made small. As a result, the parasitic capacitance generated between the gate electrode 13 and the source layer 19 can be decreased.

Furthermore, by locating the central section of the upper surface 15a in the width direction to be lower than both end sections, in the process shown in FIG. 4C, at the time of forming the carrier pulling out layer 20, carrier pulling out layer 20 can be formed at a position equal to source 19 or at a position that is lower than the source 19. Moreover, the source contact 26a of the source electrode 26 can be extended to a position lower than the upper surface of the source layer 19. As a result, an electron hole generated in the semiconductor device 1 can be eliminated effectively through the carrier pulling out layer 20 and source electric contact 26a.

In addition, the contact area of the side wall 17 and the mesa section 15 is increased by making the upper surface 15a not only just a slanted surface but a round shape as well. As a result, in the process shown in FIG. 4B, the amount of dopants diffused from the side wall 17 into the mesa section 15 increases and the source layer 19 can be efficiently formed. Moreover, the contact resistance between the side wall 17 and the source layer 19 can be made small.

Further, in the first embodiment, the side wall 17 is formed by silicon containing dopants. Therefore, the side wall 17 is a conductor. The source electrode 26 can thus be connected to the source layer 19 by passing through the side wall 17. As a result, as compared to the case wherein the side wall 17 is formed by insulating material, the electrical resistance between the source electrode 26 and the source layer 19 can be reduced.

Moreover, in the first embodiment, in the process shown in FIG. 4B, the source layer 19 is formed on the upper section of the mesa section 15 by diffusing the dopants contained in the side wall 17 into the mesa section 15. Therefore, in the source layer 19, the concentration of the dopants is highest near the boundary of the side wall 17. As a result, the contact resistance of the side wall 17 and the source layer 19 decreases. The electrical resistance between the source electrode 26 and the source layer 19 further decreases.

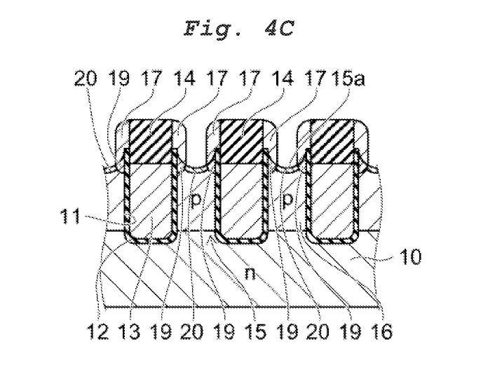

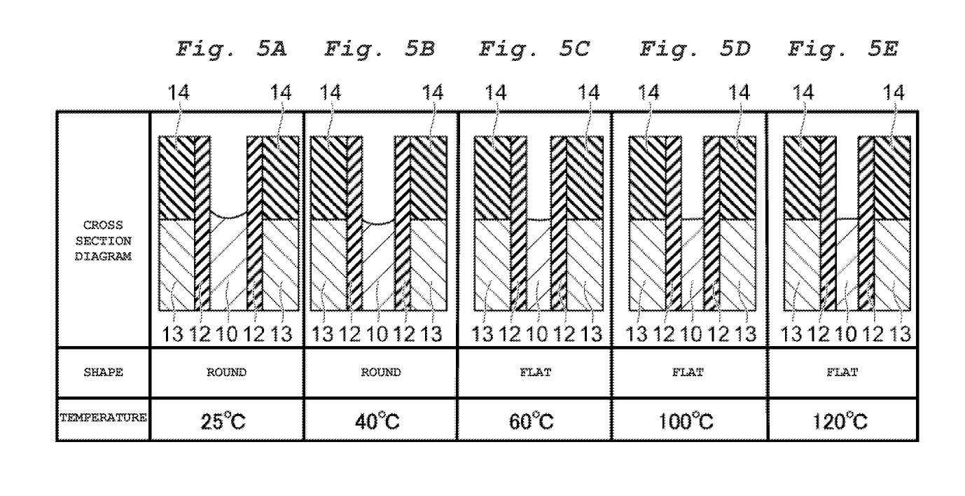

Reasons for numerical limits in the first embodiment are described below with reference to FIGS. 5A-7. In one example implementation of the first embodiment, the temperature of the CDE is 40° C. or less.

FIG. 5A to FIG. 5E are cross-sectional drawings of SEM (scanning electron microscope) photos. The drawings show a sample semiconductor device, which has undergone a CDE at different temperatures, after the sample is trenched.

At the time of performing the CDE, the mixed gas of CF₄ gas and O₂ gas is used as an etching gas. The flow rate of the CF₄ gas is 80 sccm. The flow rate of the O₂ gas is 130 sccm. Accordingly, the ratio of the flow rate of the O₂ gas (“gas flow ratio”) to the flow rate of the CF₄ gas is 1.625(=130/80). The pressure is 30 Pa. The output of the microwave is 700 W.

As shown in FIGS. 5A-5B, when the temperature is 25° C. or 40° C., the upper surface of the mesa section becomes round to have a concave shape. On the other hand, as shown in FIGS. 5C-5E, when the temperature is 60° C., 100° C., and 120° C., the upper surface of the mesa section becomes a smooth flat shape. Therefore, at the time of recessing the upper surface of the mesa section by performing CDE, if the temperature is 40° C. or less, the round shape can be formed.

A reason for forming the working surface in a round shape by decreasing the temperature of CDE is described below.

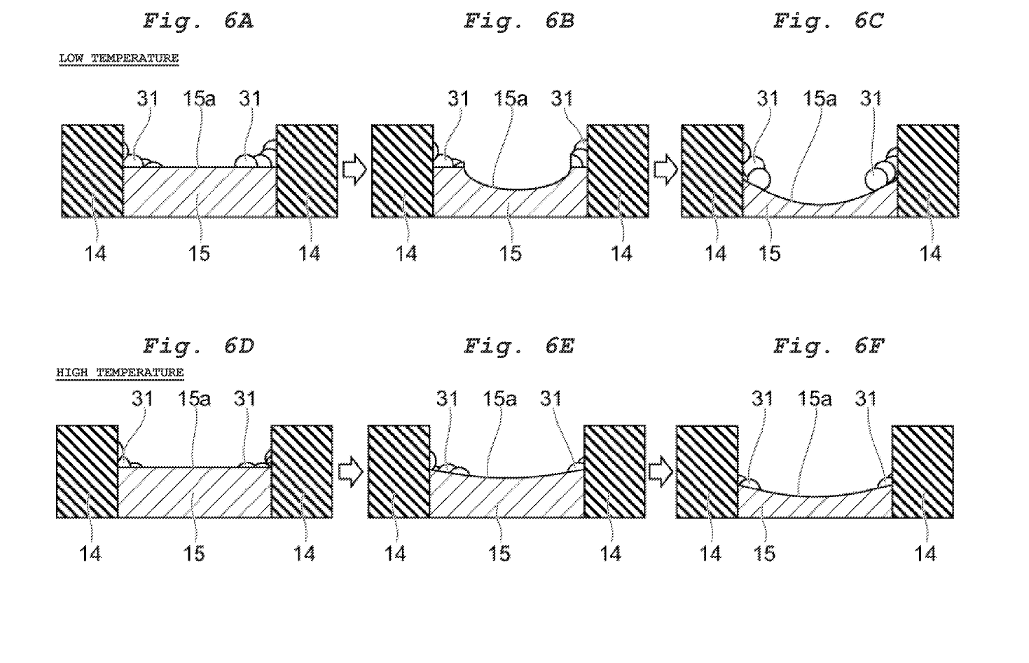

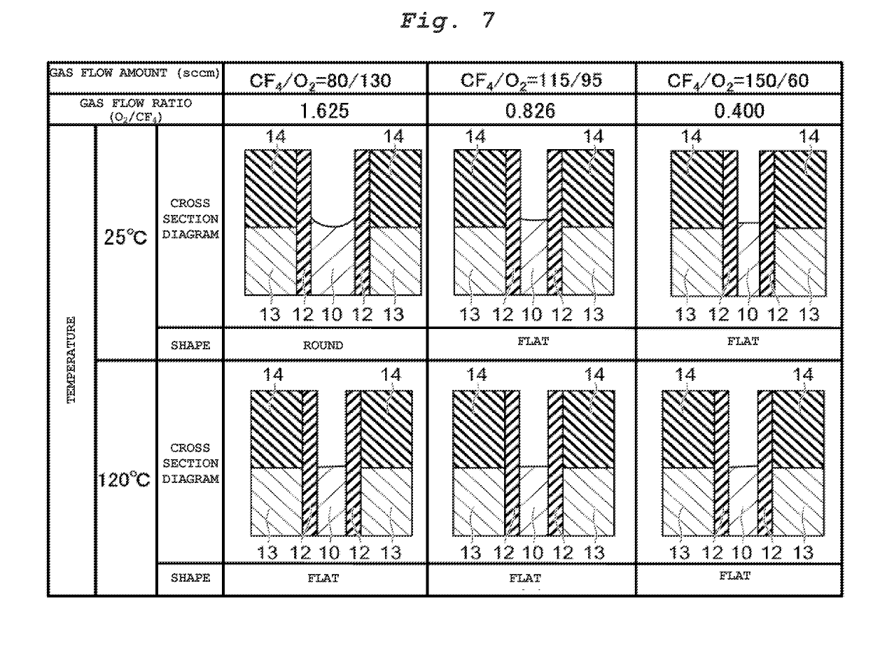

FIGS. 6A-6C are cross-sectional diagrams that show a mechanism by which a working surface becomes round when the temperature is relatively low.

FIGS. 6D-6F are cross-sectional diagrams that show a mechanism by which a working surface becomes flat when the temperature is relatively high.

As shown in FIG. 6A, when the temperature is relatively low, the equilibrium vapor pressure of a corner section formed by the side surface of the insulating section 14 and the upper surface 15a of the mesa section 15 is low. Therefore, the silicon after being removed from the mesa section 15 by performing etching is easily deposited again on the corner section as a deposition substance 31.

As a result, as shown in FIG. 6B, for the upper surface 15a of the mesa section 15, etching can be performed at the desired time starting from the central section in the width direction where deposition substance 31 is relatively thin.

As a result, as shown in FIG. 60, etching advances to the side of the central section in the width direction as compared to both ends in the width direction in the upper surface 15a, and the shape of the upper surface 15a becomes concave.

On the other hand, as shown in FIG. 6D, when the temperature is relatively high, since the equilibrium vapor pressure of the corner section is high, the re-deposition of the silicon after being removed is not caused easily and there is less deposition substance 31.

Therefore, as shown in FIG. 6E, in the upper surface 15a, the etching progresses relatively uniformly.

As a result, as shown in FIG. 6F, the shape of the upper surface 15a becomes smooth and flat.

In another example implementation of the first embodiment, the ratio of flow rate of O₂ gas to flow rate of CF₄ gas is 1.6 or more.

FIG. 7 is a cross-sectional view of SEM photos that show the sample, on which CDE is performed at mutually different temperatures and gas flow ratios, after the sample is traced. For example, when the flow rate of the CF₄ gas is 80 sccm and the flow rate of the O₂ gas is 130 sccm, the gas flow amounts are shown as “CF₄/O₂=80/130”.

As shown in FIG. 7, when the temperature is 25° C. and the gas flow ratio (e.g., ratio of the flow rate of the O₂ gas to the flow rate of the CF₄ gas) is 1.625, the shape of the upper surface of the mesa section becomes round. On the other hand, when the temperature is 25° C. and the gas flow ratio is 0.826 and 0.400, the shape of the upper surface of the mesa section becomes flat. Typically, only when the proportion of the O₂ gas is high does the oxidation tendency of the atmosphere become strong, making it easy to generate the deposition substance on the working surface. Moreover, when the temperature is 120° C., even if the gas flow ratio is any of the 1.625, 0.826, or 0.400, the shape of the upper surface of the mesa section becomes flat.

Thus, in CDE where the upper surface 15a of the mesa section 15 is recessed, if the temperature is 40° C. or less and the gas flow ratio is 1.6 or more, the shape of the upper surface 15a can be made round. The effect of the temperature on the shape of the upper surface 15a and the effect of the gas flow ratio on the shape of the upper surface 15a are mutually independent.

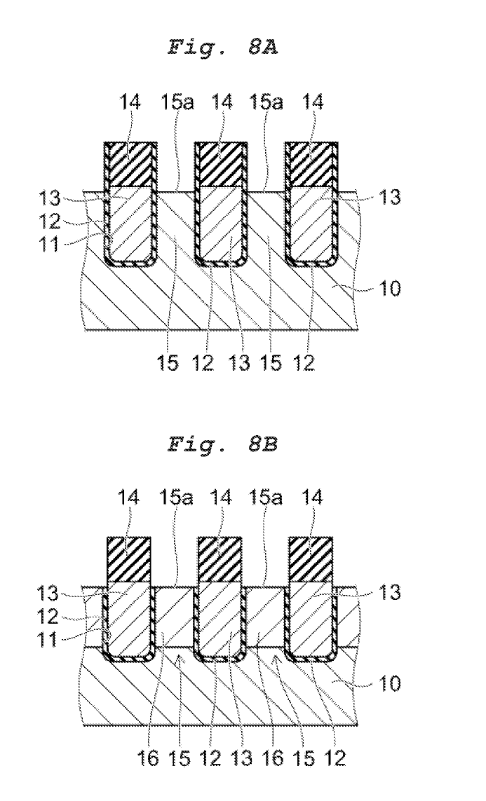

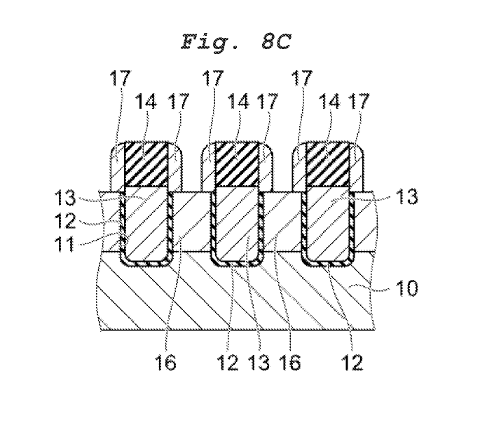

FIGS. 8A-8C are process sectional diagrams that show a method of manufacturing a semiconductor device according to a first comparative example.

In the first comparative example, the shape of the upper surface 15a in the mesa part 15 is coned to be flat and the height is reduced compared to the height of the upper surface of the gate electrode 13.

After executing the process shown in FIGS. 2A-3A, as shown in FIG. 8A, the CDE is performed for the mesa section 15, with the upper surface 15a being located at the side lower than the upper surface of the gate electrode 13. At this time, as for the conditions of CDE, the gas flow rate is less than 1.6, and/or the temperature is higher than 40° C. As a result, the upper surface 15a becomes flat.

In this case, as shown in FIG. 8B, when wet etching is performed with the use of dilute phosphoric acid, one section of the section that covers the gate electrode 13 in ate insulator 12 is removed and the gate electrode 13 is exposed.

Accordingly, as shown in FIG. 8C, when the side wail 17 is formed, the side wall 17 comes in contact with the gate electrode 13. As a result, after the semiconductor device is comply formed, the source electrode 26 (refer to FIG. 1) is short-circuited with the gate electrode 13.

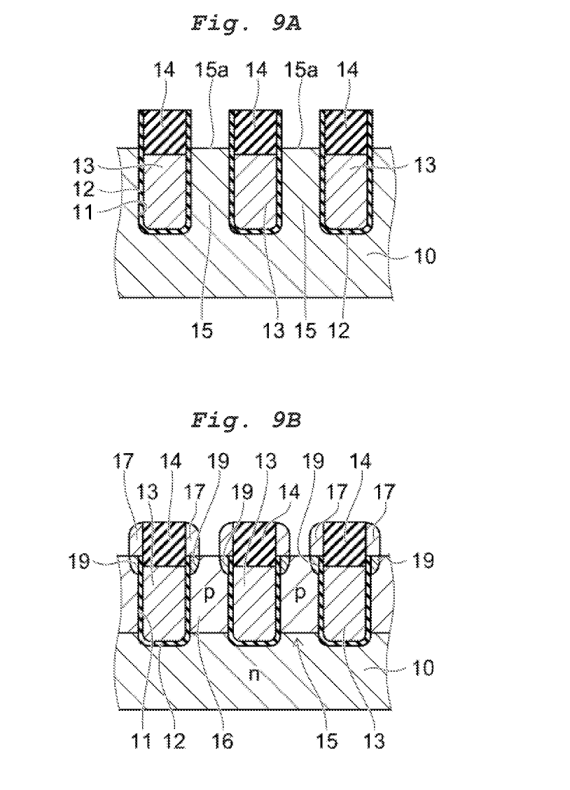

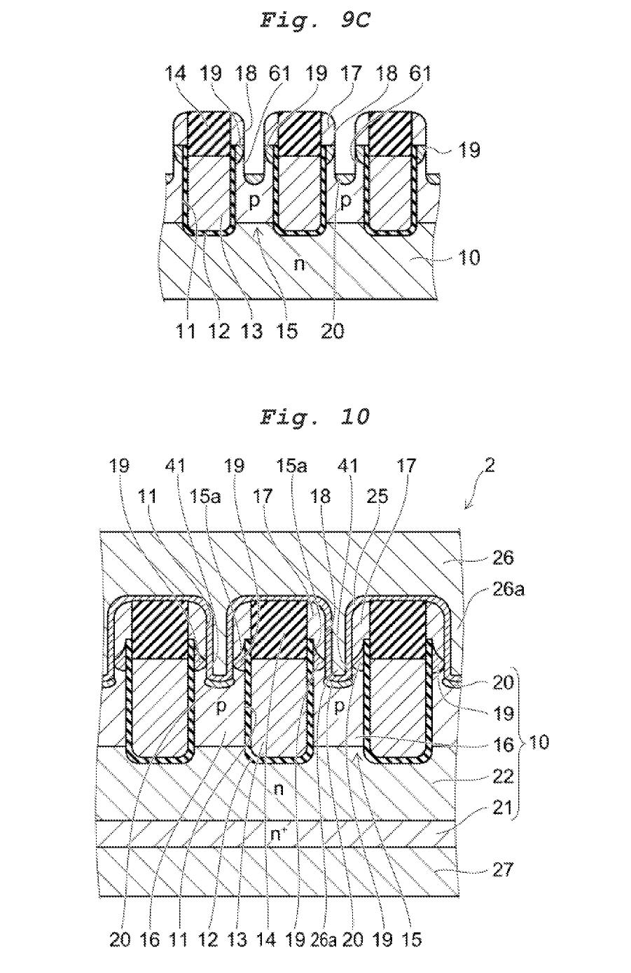

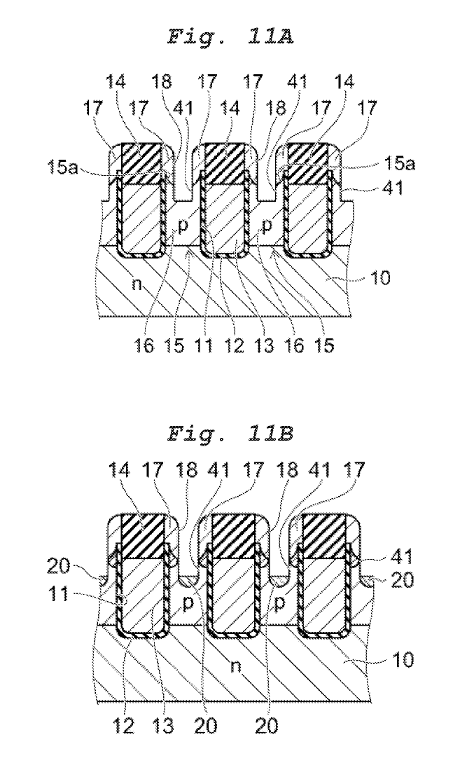

FIGS. 9A-9C are cross-sectional diagrams that show a method of manufacturing a semiconductor device according to a second comparative example.

In this second comparative example, the shape of the upper surface 15a in the mesa section 15 is considered to be flat, and the height is increased compared to the upper surface of the gate electrode 13.

After executing the process shown in FIGS. 2A-3A, as shown in FIG. 9A, CDE is performed for the mesa section 15, with the upper surface 15a being located at the side higher than the surface of the gate electrode 13. At this time, as for the conditions of CDE, the gas flow rate is less than 1.6, and/or the temperature is higher than 40° C. As a result, the upper surface 15a becomes flat.

The process shown in FIG. 3C and FIG. 4A is executed. Next, as shown in FIG. 9B, the source layer 19 is formed. At this time, since the upper surface 15a is located at the side higher than the upper surface of the gate electrode 13, the source layer 19 is formed thick so that the source layer 19 may over lap with the gate electrode 13.

As shown in FIG. 9C, the carrier pulling layer 20 is formed. At this time, the central section in the width direction of the upper surface 15a is located at the side higher than the upper surface of the gate electrode 13. Accordingly, while the need to form the carrier pulling layer 20 at the position where an electron hole in the semiconductor device can be effectively eliminated, it is necessary to form a deep trench 61 in the area immediately below the source trench 13, and to form the carrier pulling layer 20 at the lower side. Therefore, the difficulty level of manufacturing process is increased; the miniaturization of the semiconductor device becomes difficult; and the manufacturing cost of the semiconductor device is increased.

### Second Embodiment

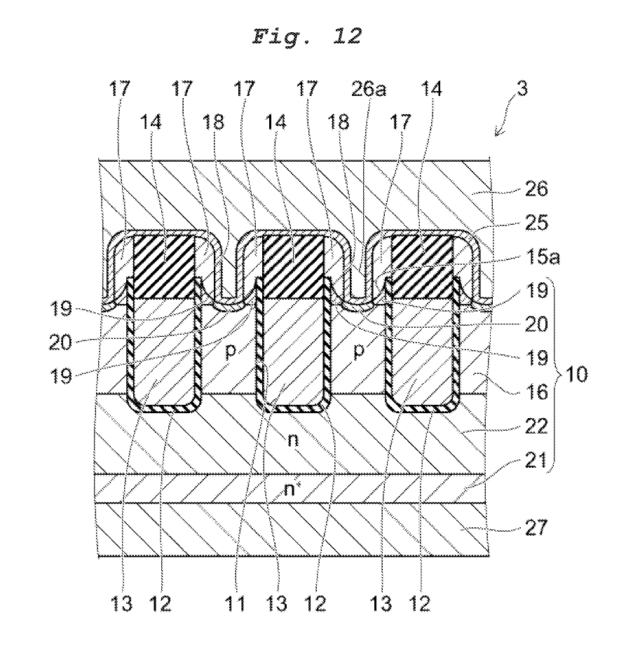

FIG. 10 is a cross-sectional drawing that shows a semiconductor device according to a second embodiment. A carrier pulling trench 41 is further formed at the upper surface 15a of the mesa section 15. This point is different in the second embodiment as compared to the first embodiment. The barrier metal layer 25 is formed on the inner surface of the carrier pulling trench 41. The lower part of the source contact 26a moves into the carrier pulling trench 41. The carrier pulling layer 20 is formed in the part of the mesa section 15 that is connected to the bottom surface of the carrier pulling trench 41.

FIGS. 11A and 11B are cross-sectional diagrams that show a method of manufacturing the semiconductor device according to the second embodiment. Only the caper part of the middle structure of the semiconductor device 2 is shown in FIGS. 11A-11B. The process shown in FIGS. 2A-3C is executed. Next, as shown in FIG. 4A, the silicon film is formed on all the surfaces. Subsequently, the side wall 17 is formed by back-etching.

In the second embodiment, as shown in FIG. 11A, even after exposing the upper surface 15a in the mesa section 15, the etching is continued for the silicon film, and over-etching is done. As a result, the carrier pulling trench 41 is formed in the area that is not covered by the side wall 17 in the upper surface 15a.

As shown in FIG. 11B, the source layer 19 is formed in the part of the mesa section 15 that is connected to the side wall 17 by heat treatment. The carrier pulling layer 20 is formed in the area that is immediately beneath the carrier pulling trench 41 by ion implantation of the acceptor dopants. The subsequent process is similar to the first embodiment.

According to the second embodiment, the carrier pulling layer 20 can be formed lower as compared to the first embodiment. As a result, the electron hole generated in the semiconductor device 2 is more certainly trapped, and the electron hole can be eliminated by the carrier pulling layer 20.

In this case, the shape of the upper surface 15a in the mesa section 15 becomes round immediately before the formation of the carrier pulling trench 41. Since the central section in the width direction of the upper surface 15a is position lower than both end sections, the depth of formation of the carrier pulling trench 41 can be reduced as compared to the second comparative example.

In the second embodiment, the composition, manufacturing method and effects other than described above are substantially the same as the first embodiment.

### Third Embodiment

FIG. 12 is a cross-sectional diagram that shows a semiconductor device according to a third embodiment. The lower surface of the source layer 19 is flat and the lower surface of the carrier pulling layer 20 is located lower than the lower side of the source layer 19. This point is different in the third embodiment as compared to the first embodiment.

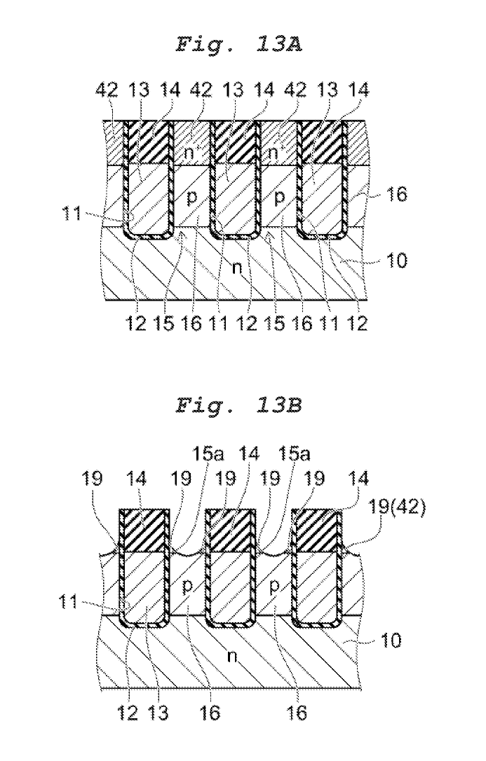

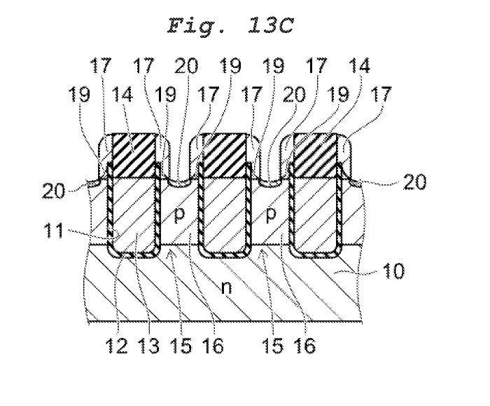

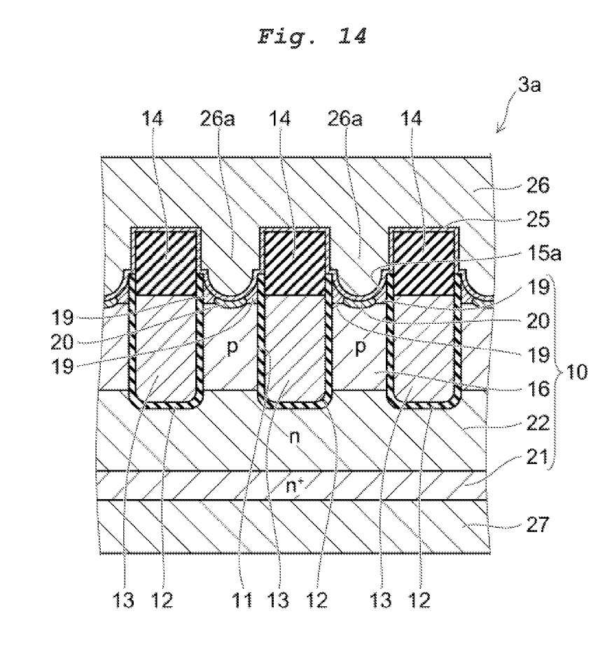

FIGS. 13A-13C are cross-sectional diagrams that show a method of manufacturing the semiconductor device according to the third embodiment. Only the upper part of the middle structure of a semiconductor device 3 is shown in FIGS. 13A-13C. The process shown in FIGS. 2A-3A is executed.

As shown in FIG. 13A, the p-type base layer 16 is formed in the mesa section 15 by ion implantation of the acceptor dopants in all surfaces. The semiconductor type of the upper section in the base layer 16 is inverted to n+ from the p type by ion implantation, of acceptor dopants in substantially al surfaces and an n+ type layer 42 is formed.

As shown in FIG. 13B, CDE is applied and the upper surface 15a in the mesa section 15 is reversed. The conditions of this CDE are substantially the same as the conditions of CDE (refer to FIG. 3B) in the first embodiment. As a result, the shape of the upper surface 15a becomes curved to have a concave shape. In the third embodiment, the upper surface 15a in the central section in the width direction of the mesa section 15 is located lower than the lower surface of the n+ type layer 42, and the upper surface 15a at both ends in the width direction of the mesa section 15 is located higher than the upper surface of the n+ type layer 42. In this manner, the n+ type layer 42 is removed from the central section in width direction of the mesa section 15. On the other hand, the n+ type layer 42 is retained and is transformed into the source layer 19 at both ends in the width direction of the mesa section 15.

As shown in FIG. 13C, the naturally oxidized film (not shown in the drawing) that is formed on the upper surface 15a is removed by wet etching, for which dilute phosphoric acid is used. At this time, the exposed part of gate insulator 12 is removed. However, the part that covers the gate electrode 13 in gate insulator 12 is covered by the mesa section 15. This section is not removed. The side wall 17 is then formed. The insulating section 14 and the side wall 17 are used as a mask and the carrier pulling layer 20 is formed at the central section in the width direction of the mesa section 15 by ion implantation of the acceptor dopants. The subsequent process is similar to that of the first embodiment.

According to the third embodiment, the carrier pulling trench 41 (refer to FIG. 11A) cannot be formed and the carrier pulling layer 20 can be arranged at the side lower than the source layer 19. The carrier pulling trench 41 can be formed to arrange the carrier pulling layer 20 at the lower side.

Moreover, in the embodiment, in the process shown in FIG. 13A, the n+ type layer 42 is formed by ion implantation. In the process shown in FIG. 13B, the upper surface 15a is round and the source layer 19 is formed using the round the upper surface 15a and by selectively removing the n+ type layer 42. Accordingly, the self-aligned source layer 19 can be formed without depending on thermal diffusion.

Accordingly, in the embodiment, the material in the side wall 17 is not limited to silicon that contains dopants. So, the design-freedom degree is higher for the semiconductor device 3. For instance, if the side wall 17 is formed with metallic material, the electrical resistance between the source electrode 26 and the source layer 19 can be decreased further. Moreover, if the side wall 17 is formed with the insulating material such as silicon oxides, the insulation properties between the source electrode 26 and the gate electrode 13 are improved more. The parasitic capacitance can be decreased. Moreover, the side wall 17 can be omitted.

Other than the above configuration in the third embodiment, the manufacturing method and the effects are substantially the same as those described in the first embodiment.

The modified example of the third embodiment is explained. FIG. 14 is a cross-sectional diagram that shows a semiconductor device according to a modified example of the third embodiment.

As shown in FIG. 14, the fact that the side wall 17 is not formed is the difference between a semiconductor device 3a as compared to the semiconductor device 3 (refer to FIG. 12) in the third embodiment. That is, the modified example omits the side wall 17 in the semiconductor device 3 of the third embodiment.

The semiconductor device 3a can be manufactured by not forming the side wall 17 in the process shown in FIG. 13C. However, in this case, the ion implantation of acceptor dopants to form the carrier pulling layer 20 is done for the entire the upper surface 15a. The dose amount is set so that the conductivity type of source 19 is not inverted to the p-type from the n-type.

According to this modified example of the third embodiment, the source electrode 26 can reduce the electrical resistance between source layers 19, as compared to the third embodiment. Moreover, the number of processes can be reduced in the manufacturing process of the semiconductor device and the manufacturing cost can be reduced. Otherwise, the composition, manufacturing methods, and the effects are similar to the third embodiment.

Accordingly, a miniaturized semiconductor device with high reliability and a manufacturing method thereof can be achieved by the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying Claims and their equivalents are intended to cover such forms or modifications as would fall within the scope and spirit of the inventions.

What is claimed is:

1. A semiconductor device comprising:
a semiconductor substrate having multiple gate trenches and a curved section between two of the gate trenches formed on an upper surface of the semiconductor substrate, a drain layer of a first conductivity type, a base layer of a second conductivity type between the gate trenches, and a source layer of the first conductivity type at both ends of the curved section;
a gate insulating film formed on an inner surface of the gate trenches;
gate electrodes each embedded in a lower part of the gate trenches;
an insulating section having an upper part that protrudes above the upper surface of the semiconductor substrate and a lower part that is disposed on upper surfaces of the gate electrodes;
a source electrode that is electrically connected to the source layer; and
a drain electrode that is electrically connected to the drain layer.

2. The semiconductor device according to claim 1, wherein the semiconductor substrate further includes a carrier pulling layer above the base layer having an effective dopant concentration that is higher than an effective dopant concentration of the base layer.

3. The semiconductor device according to claim 2, wherein a lower surface of the carrier pulling layer is located below a lower surface of the source layer.

4. The semiconductor device according to claim 2, wherein a lower surface of the carrier pulling layer is located above a lower surface of the source layer.

5. The semiconductor device according to claim 1, wherein the semiconductor substrate further includes a source trench formed through the upper surface of the curved section, and the source electrode extends into the source trench.

6. The semiconductor device according to claim 1, further comprising:
side wails that are formed on sides of the insulating section, and made of silicon that contains dopants of the first conductivity type.

7. The semiconductor device according to claim 6, wherein the source layer contains dopants of the first conductivity type that are the same as the dopants contained in the silicon of the insulating section.

8. The semiconductor device according to claim 1, wherein the source layer is a part of the curved section and has a curved upper surface.

9. The semiconductor device according to claim 1, wherein, the source layer is not a part of the curved section and has a flat upper surface.

10. A semiconductor device comprising:
a semiconductor substrate having a concave upper surface and gate trenches on both sides of the concave upper surface, a source layer of the first conductivity type at both ends of the concave upper surface, a base layer of a second conductivity type between the gate trenches, and a drain layer of the first conductivity type below the base layer;
a gate insulating film formed on an inner surface of the gate trenches;
gate electrodes each embedded in a lower part of the gate trenches;
a source electrode that is electrically connected to the concave upper surface; and
a drain electrode that is electrically connected to the drain layer.

11. The semiconductor device according to claim 10, wherein the semiconductor substrate further includes a carrier pulling layer above the base layer having an effective dopant concentration that is higher than an effective dopant concentration of the base layer.

12. The semiconductor device according to claim 11, wherein a lower surface of the carrier pulling layer is located below a lower surface of the source layer.

13. The semiconductor device according to claim 11, wherein a lower surface of the carrier pulling layer is located above a lower surface of the source layer.

14. The semiconductor device according to claim 10, wherein the semiconductor substrate further includes a source trench formed through the concave upper surface, and the source electrode extends into the source trench.

15. A method of manufacturing a semiconductor device, comprising:
forming multiple gate trenches in a semiconductor substrate having a drain layer of a first conductivity type and a base layer of a second conductivity type above the drain layer and between the gate trenches;
forming a gate insulating film made of silicon oxide on inner surfaces of the gate trenches;
forming a gate electrode on a lower part of each gate trench;
forming an insulating section on an upper part of each gate trench;
forming a curved concave section on an upper surface of the semiconductor substrate so that both ends of the curved concave section is located higher than an upper surface of the gate electrode;
forming a source layer of a first conductivity type at both ends of the curved concave section;
forming a source electrode electrically connected to the source layer; and
forming a drain electrode electrically connected to the drain layer.

16. The method of claim 15, wherein the curved concave section is formed by performing chemical dry etching under conditions where a ratio of a flow rate of oxygen gas to a flow rate of carbon tetrafluoride gas is 1.6 or more and the temperature is 40° C. or less.

17. The method of claim 15, wherein said forming the source layer comprises:
forming side walls made of silicon containing dopants of the first conductivity type on side surfaces of the insulating section; and
diffusing the dopants contained in the side walls into the both ends of the curved concave section.

18. The method of claim 17, further comprising:
forming a carrier pulling layer having an effective dopant concentration higher than an effective dopant concentration of the base layer, which is of the second conductivity type above the base layer.

19. The method of claim 18, wherein a lower surface of the carrier pulling layer is located below a lower surface of the source layer.

20. The method of claim 17, further comprising:
forming a source trench at a center region of the curved concave section by etching, using the insulating section and the side walls as a mask.
